(19) United States
(12) Patent Application Publication
(10) Pub. No.: US 2025/0324777 A1
(43) Pub. Date: Oct. 16, 2025

(54) GROUP-III NITRIDE DEVICE AND PREPARATION METHOD THEREOF

(71) Applicants: University of Science and Technology of China, Hefei (CN); Anhui University, Hefei (CN); Delta Electronics (Shanghai) Co., Ltd., Shanghai (CN)

(72) Inventors: Shu Yang, Hefei (CN); Xi Tang, Hefei (CN); Xiuyi Bian, Hefei (CN); Xiaoyu Liu, Anhui (CN)

(21) Appl. No.: 19/092,851

(22) Filed: Mar. 27, 2025

(30) Foreign Application Priority Data
Apr. 12, 2024 (CN) 202410445289.1

(51) Int. Cl. H10F 30/28; H10D 30/01; H10D 30/47; H10D 62/824; H10D 62/85; H10D 64/27; H10F 71/00; H10F 77/124; H10F 77/20

(52) U.S. Cl. CPC H10F 30/2877; H10D 30/015; H10D 30/476; H10D 64/411; H10F 71/1278; H10F 77/254; H10D 62/824; H10D 62/8503; H10F 77/1246

(57) ABSTRACT

The disclosure provides a group-III nitride device. The group-III nitride device includes a heterojunction epitaxial wafer and at least one island-shaped electrode. The at least one island-shaped electrode of the group-III nitride device is disposed on the heterojunction epitaxial wafer. Each of the at least one island-shaped electrode includes an interconnection metal layer and at least one island-shaped structural layer. The island-shaped structural layer is covered by the interconnection metal layer and connected to the interconnection metal layer.

### CROSS-REFERENCE TO RELATED APPLICATIONS

This application claims priority to China Patent Application No. 202410445289.1, filed on Apr. 12, 2024. The entire contents of the above-mentioned patent application are incorporated herein by reference for all purposes.

### FIELD OF THE INVENTION

The present disclosure relates to a semiconductor device, and more particularly to a group-III nitride device and a preparation method of the group-III nitride device.

### BACKGROUND OF THE INVENTION

Currently, group-III nitride materials, e.g., gallium nitride (GaN), is one of the most favored semiconductor materials. For example, GaN possesses exceptional material characteristics, including a high electron saturation drift velocity of up to 2.5×10\hat{ }7 cm/s, a wide bandgap of up to 3.4 eV, the excellent thermal stability, the outstanding radiation resistance, and the high breakdown field strength of up to 2.2 MV/cm. Moreover, in the aluminum gallium nitride/gallium nitride (AlGaN/GaN) heterojunction interface, spontaneous and piezoelectric polarization effects occur, resulting in the formation of high mobility and high-density two-dimensional electron gas. Due to the excellent characteristics, gallium nitride has become a focal point of research domestically and internationally. In addition, gallium nitride has been extensively applied to many fields such as optoelectronics, power electronics, and radio frequency electronics.

Due to the advantages such as visible-blindness, high quantum efficiency, operation at room temperature, high temperature resistance, good chemical corrosion resistance, and strong radiation tolerance, gallium nitride ultraviolet (UV) photodetectors have significant application value in spacecraft fields, fire detection fields, UV communication fields and similar fields. One of the key performance parameters of UV photodetectors is their ability to effectively collect photo-generated carriers in the active region under UV illumination. High-performance photodetectors should generate a sufficiently strong field for carrier collection, and the generated field needs to cover the areas where carriers are generated as much as possible. Traditional photodetectors often utilize interdigitated electrode structures, where the depletion region extends from the electrode to both sides. In other words, the depletion efficiency is low. Moreover, since the interdigital electrode is not opaque, the area percentage of the depletion region is limited. Under this circumstance, the gain and responsivity of the photodetector cannot be further improved. In order to fabricate a high-performance gallium nitride UV photodetector, it is important to design a novel structure of the gallium nitride UV photodetector while improving the absorption of photons in the depletion region.

GaN is also an important material in the field of power electronics. For example, a lateral GaN high electron mobility transistor (HEMT) and a lateral field-effect rectifier (L-FER) are ones of the current mainstream technologies. Generally, in the GaN HEMT or the GaN L-FER, the on/off states of the underlying two-dimensional electron channel are controlled through the gate electrode or the anode electrode. In some application scenarios, there may be significant leakage current issues caused by source-drain or cathode-anode punch-through capability in the off state.

Therefore, there is a need of providing an improved group-III nitride device and a preparation method of the group-III nitride device in order to overcome the drawbacks of the conventional technologies.

### SUMMARY OF THE INVENTION

The present disclosure provides a group-III nitride device and a preparation method of the group-III nitride device. The group-III nitride device includes at least one island-shaped electrode. Due to the island-shaped electrode, the depletion region under the bias condition can be expanded to the region around the island-shaped electrode. Consequently, the electric field in the depletion region has more obvious depletion effect on the charge carriers. For example, the group-III nitride device is a photodetector, and the at least one island-shaped electrode is served as a positive electrode and/or a negative electrode of the photodetector. Furthermore, the use of a translucent interconnection metal layer can solve the light-blocking problem of the electrode and increase the effective absorption of photons in the depletion region. Consequently, the photocurrent is increased. In case that the group-III nitride device is a high electron mobility transistor (HEMT) and the at least one island-shaped electrode is served as a gate electrode of the HEMT, the leakage current of the HEMT can be effectively reduced, and the source-drain punch-through probability of the HEMT in an off state can be decreased. Alternatively, the group-III nitride device is a lateral field effect rectifier (L-FER) and the at least one island-shaped electrode is served as an anode electrode of the L-FER, the leakage current of the L-FER is reduced, and the on-resistance of the L-FER in the on state is also reduced.

In accordance with an aspect of the present disclosure, a group-III nitride device is provided. The group-III nitride device includes a heterojunction epitaxial wafer and at least one island-shaped electrode. The at least one island-shaped electrode of the group-III nitride device is disposed on the heterojunction epitaxial wafer. Each of the at least one island-shaped electrode includes an interconnection metal layer and at least one island-shaped structural layer. The island-shaped structural layer is covered and connected by the interconnection metal layer.

In an embodiment, a depletion region of the at least one island-shaped electrode under a bias condition is expanded to a region around the at least one island-shaped electrode.

In an embodiment, after the heterojunction epitaxial wafer is downwardly etched, at least one hole-shaped groove is formed. Each of the at least one island-shaped structural layer is formed in the corresponding hole-shaped groove.

In an embodiment, a depth of the hole-shaped groove is ranged between 60 nm and 100 nm.

In an embodiment, a thickness of the island-shaped structure layer is ranged between 80 nm and 120 nm. The island-shaped structure layer in the hole-shaped groove and the heterojunction epitaxial wafer are contacted with each other.

In an embodiment, the island-shaped structure layer is made of a metallic material, a semiconductor material, or a combination thereof.

In an embodiment, the interconnection metal layer is made of nickel, gold, palladium, platinum, titanium, titanium nitride, conductive glass, or a combination thereof.

In an embodiment, the group-III nitride device is a photodetector and the at least one island-shaped electrode is served as a positive electrode or a negative electrode of the photodetector.

In an embodiment, the interconnection metal layer is a translucent interconnection metal layer.

In an embodiment, a thickness of the translucent interconnection metal layer is ranged between 5 nm and 10 nm.

In an embodiment, the group-III nitride device is a high electron mobility transistor and the at least one island-shaped electrode is served as a gate electrode of the high electron mobility transistor.

In an embodiment, the group-III nitride device is a lateral field effect rectifier and the at least one island-shaped electrode is served as an anode electrode of the lateral field effect rectifier

In accordance with another aspect of the present disclosure, a preparation method of a group-III nitride device is provided. The preparation method of the group-III nitride device includes steps of: (S1) providing a heterojunction epitaxial wafer; (S2) defining an island-shaped structure layer region on the heterojunction epitaxial wafer, and performing an etching process to form a hole-shaped groove in the heterojunction epitaxial wafer corresponding to the island-shaped structure layer region; (S3) forming an island-shaped structure layer in the hole-shaped groove; and (S4) defining an interconnection metal layer region and forming an interconnection metal layer on the interconnection metal layer region, wherein the island-shaped structural layer is covered and connected by the interconnection metal layer, and the island-shaped structural layer and the interconnection metal layer are collaboratively formed as at least one island-shaped electrode.

Preferably, in the step (S2), the etching process is an inductively coupled plasma etching process.

In an embodiment, the heterojunction epitaxial wafer includes a substrate, a buffer layer, a channel layer and a barrier layer from bottom to top. Moreover, in the step (S2), the hole-shaped groove is formed after a portion of the barrier layer and a portion of the channel layer corresponding to the island-shaped structure layer region are etched.

Preferably, in the step (S3), an electron beam evaporation deposition process is performed to deposit a material of the island-shaped structure layer in the hole-shaped groove, so that the island-shaped structure layer is formed.

Preferably, in the step (S4), an electron beam evaporation deposition process is performed to deposit a material of the interconnection metal layer on the interconnection metal layer region, so that the interconnection metal layer is formed.

From the above descriptions, the present disclosure provides a group-III nitride device. Due to the island-shaped electrode, the depletion region under the bias condition can be expanded to the region around the island-shaped electrode. Consequently, the electric field in the depletion region has more obvious depletion effect on the charge carriers. For example, the group-III nitride device is a photodetector, and the at least one island-shaped electrode includes a positive electrode and a negative electrode of the photodetector. Furthermore, the use of a translucent interconnection metal layer can solve the light-blocking problem of the electrode and increase the effective absorption of photons in the depletion region. Consequently, the photocurrent is increased. In case that the group-III nitride device is a high electron mobility transistor (HEMT) and the at least one island-shaped electrode includes a gate electrode of the HEMT, the leakage current of the HEMT can be effectively reduced, and the source-drain punch-through probability of the HEMT in an off state will be decreased. Alternatively, the group-III nitride device is a lateral field effect rectifier (L-FER) and the at least one island-shaped electrode includes an anode electrode of the L-FER, the leakage current of the L-FER is reduced, and the on-resistance of the L-FER is in the on state is also reduced.

The present disclosure also provides a preparation method of the group-III nitride device. The island-shaped electrode fabrication technology and the device fabrication processes are integrated. For example, an inductively coupled plasma reactive ion etching technology is used to etch the heterojunction epitaxial wafer to form the hole-shaped groove. Furthermore, a self-alignment technology is adopted to deposit the island-shaped structure layer. After the deposition of the interconnection metal layer, the island-shaped electrode is formed.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1A is a schematic three-dimensional diagram of a group-III nitride photodetector according to a first embodiment of the present disclosure;

FIG. 1B is a schematic three-dimensional diagram of a group-III nitride high electron mobility transistor (HEMT) according to a second embodiment of the present disclosure;

FIG. 1C is a schematic three-dimensional diagram of a group-III nitride lateral field effect rectifier (L-FER) according to a third embodiment of the present disclosure;

FIG. 2A is a schematic cross-sectional diagram illustrating the region in an island-shaped structural layer of the group-III nitride photodetector shown in FIG. 1A;

FIG. 2B is a schematic cross-sectional diagram illustrating the region between adjacent island-shaped structural layers of the group-III nitride photodetector shown in FIG. 1A;

FIG. 3A is a schematic cross-sectional diagram illustrating the structure of the corresponding group-III nitride device in a step S1 of the preparation method;

FIG. 3B is a schematic cross-sectional diagram illustrating the structure of the corresponding group-III nitride device in a step S2 of the preparation method;

FIG. 3C is a schematic cross-sectional diagram illustrating the structure of the corresponding group-III nitride device in a step S3 of the preparation method;

FIG. 3D is a schematic cross-sectional diagram illustrating the structure of the corresponding group-III nitride device in a step S4 of the preparation method; and

FIG. 4 is a schematic diagram illustrating a depletion method of the island-shaped electrode of the group-III nitride device shown in FIGS. 3A to 3D.

### DETAILED DESCRIPTION OF THE PREFERRED EMBODIMENT

In order to facilitate understanding of the technical means, creative features, achievements, and effects achieved by the present disclosure, the present disclosure will now be described more specifically with reference to the following embodiments. However, the following embodiments are only preferred but not all embodiments of the present disclosure. Based on the following embodiments, other embodiments obtained by those skilled in the art without creative labor are within the scope of the present disclosure. The experimental methods in the following embodiments, unless otherwise specified, are conventional methods, and the materials, reagents, etc., used in the following embodiments can be obtained from commercial sources unless otherwise specified.

In a first embodiment of the present disclosure, a group-III nitride photodetector is provided. The group-III nitride photodetector includes at least one island-shaped electrode. The island-shaped electrode includes an island-shaped structural layer and an interconnection metal layer. The island-shaped structural layer is covered by the interconnection metal layer and connected to the interconnection metal layer. In an embodiment, the island-shaped electrode can be served as a positive electrode and/or a negative electrode of the photodetector.

Due to the island-shaped electrode, the depletion region under the bias condition can be expanded to the region around the island-shaped electrode. Consequently, the electric field in the depletion region has more obvious depletion effect on the charge carriers. Furthermore, the use of a translucent interconnection metal layer can solve the light-blocking problem of the electrode and increase the effective absorption of photons in the depletion region. Consequently, the photocurrent is increased.

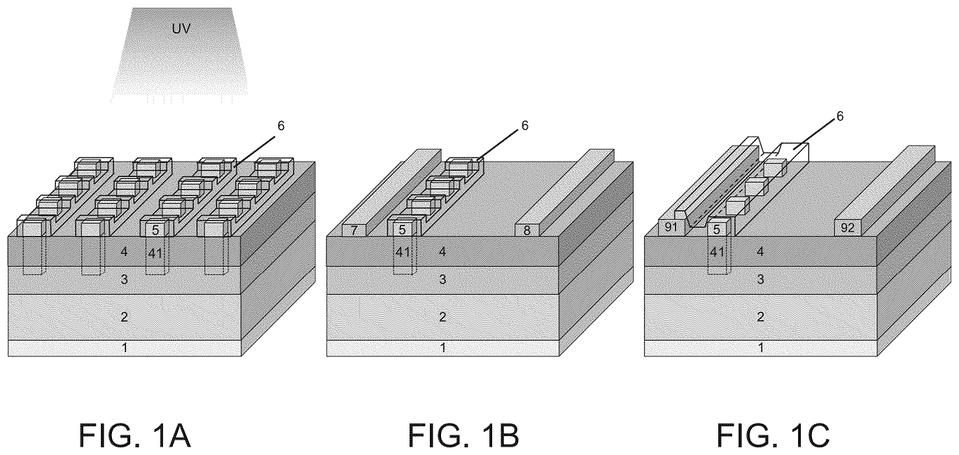

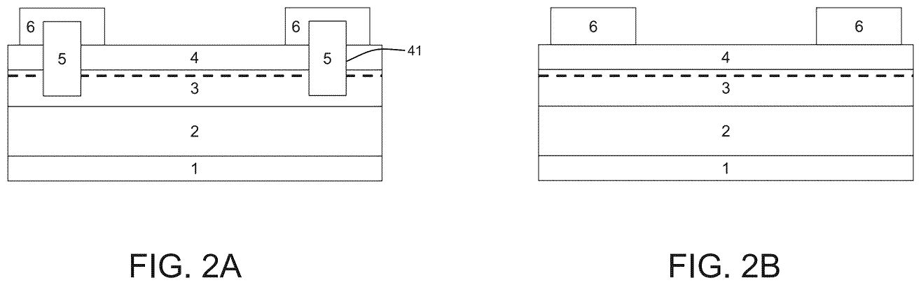

Please refer to FIGS. 1A, 2A and 2B. FIG. 1A is a schematic three-dimensional diagram of the group-III nitride photodetector according to the first embodiment of the present disclosure. FIG. 2A is a schematic cross-sectional diagram illustrating the region in the island-shaped structural layer of the group-III nitride photodetector shown in FIG. 1A. FIG. 2B is a schematic cross-sectional diagram illustrating the region between adjacent island-shaped structural layers of the group-III nitride photodetector shown in FIG. 1A. In this embodiment, the group-III nitride photodetector includes a substrate 1, a buffer layer 2, a channel layer 3, a barrier layer 4, the island-shaped structural layer 5 and the translucent interconnection metal layer 6 from bottom to top.

For example, the substrate 1 is made of monocrystalline silicon, sapphire, gallium nitride, silicon carbide or diamond. In this embodiment, the substrate 1 is a silicon substrate.

The buffer layer 2 is made of GaN or AlGaN material, which contains C impurities. In addition, the thickness of the buffer layer 2 is usually ranged between 2 μm and 6 μm.

The channel layer 3 is made of GaN material. In addition, the thickness of the channel layer 3 is ranged between 200 nm and 500 nm.

The barrier layer 4 is made of AlGaN material. The thickness of the barrier layer 4 is ranged between 10 nm and 30 nm. In addition, the Al component incorporated in the barrier layer 4 is usually ranged between 10% and 30%.

A hole-shaped groove 41 is formed in the surface of the barrier layer 4. The depth of the hole-shaped groove 41 is ranged between 60 nm and 100 nm. In an embodiment, the hole-shaped groove 41 is formed after a portion of the barrier layer 4 and a portion of the channel layer 3 are etched.

The island-shaped structure layer 5 is made of nickel, gold, palladium, platinum, titanium, titanium nitride, or a combination thereof. In addition, the thickness of the island-shaped structure layer is ranged between 80 nm and 120 nm.

The translucent interconnection metal layer 6 is made of nickel, gold, palladium, platinum, titanium, titanium nitride, conductive glass, or a combination thereof. Preferably, the total thickness of the translucent interconnection metal layer 6 is less than 10 nm (e.g., in the range between 5 nm and 10 nm) to ensure good photon transmittance and improve photon capture efficiency.

Generally, gallium nitride is also one of the most promising candidate materials in the field of power electronics. Power electronics technology is an electronic technology used in the field of electricity. Its main purpose is to control and covert electrical energy through power electronic devices. As the sizes of the electronic device are gradually shrunk, the transistor channels also continue to be shortened. However, when the channel is shortened to a certain extent, a quantum tunneling phenomenon may easily occur. Due to the quantum tunneling phenomenon, the switching function of the transistor loses. Compared with the conventional electrode structure, the island-shaped electrode causes the depletion region to expand around the electrode under the bias voltage. Consequently, the electric field in the depletion region has more obvious depletion effect on the charge carriers. In the off state, the leakage current can be effectively reduced, and the channel control capability can be significantly improved.

In a second embodiment of the present disclosure, a group-III nitride high electron mobility transistor (HEMT) is provided. The group-III nitride HEMT includes an island-shaped electrode. The island-shaped electrode includes at least one island-shaped structural layer 5 and at least one interconnection metal layer 6. The island-shaped structural layer 5 is covered by the interconnection metal layer 6 and connected to the interconnection metal layer. In an embodiment, the island-shaped electrode can be served as a gate electrode of the HEMT.

Due to the island-shaped electrode, the depletion region under the bias condition can be expanded to the region around the island-shaped electrode. Consequently, the electric field in the depletion region has more obvious depletion effect on the charge carriers. Furthermore, the leakage current of the HEMT can be effectively reduced, and the source-drain punch-through probability of the HEMT in an off state can be decreased. In addition, the gate control capability is significantly enhanced.

FIG. 1B is a schematic three-dimensional diagram of the group-III nitride high electron mobility transistor (HEMT) according to the second embodiment of the present disclosure. In this embodiment, the group-III nitride HEMT includes a substrate 1, a buffer layer 2, a channel layer 3, a barrier layer 4, the island-shaped structural layer 5, the interconnection metal layer 6, a source electrode 7 and a drain electrode 8 from bottom to top.

For example, the substrate 1 is made of monocrystalline silicon, sapphire, gallium nitride, silicon carbide or diamond. In this embodiment, the substrate 1 is a silicon substrate.

The buffer layer 2 is made of GaN or AlGaN material, which contains C impurities. In addition, the thickness of the buffer layer 2 is usually ranged between 2 μm and 6 μm.

The channel layer 3 is made of GaN material. In addition, the thickness of the channel layer 3 is ranged between 200 nm and 500 nm.

The barrier layer 4 is made of AlGaN material. The thickness of the barrier layer 4 is ranged between 10 nm and 30 nm. In addition, the Al component incorporated in the barrier layer 4 is usually ranged between 10% and 30%.

A hole-shaped groove 41 is formed in the surface of the barrier layer 4. The depth of the hole-shaped groove 41 is ranged between 60 nm and 100 nm. In an embodiment, the hole-shaped groove 41 is formed after a portion of the barrier layer 4 and a portion of the channel layer 3 are etched.

The island-shaped structure layer 5 is made of a metallic material, a semiconductor material, or a combination thereof. For example, the metallic material is nickel, gold, palladium, platinum, titanium, titanium nitride, or a combination thereof. The semiconductor material is P-type GaN, P-type AlGaN, or a combination thereof. In addition, the thickness of the island-shaped structure layer is ranged between 80 nm and 120 nm.

The interconnection metal layer 6 is made of nickel, gold, palladium, platinum, titanium, titanium nitride, conductive glass, or a combination thereof.

The source electrode 7 and the drain electrode 8 are formed through a metal Ti/Al/Ni/Au depositing and annealing process.

In a third embodiment of the present disclosure, a group-III nitride lateral field effect rectifier (L-FER) is provided. The group-III nitride L-FER includes at least one island-shaped electrode. The island-shaped electrode includes an island-shaped structural layer 5 and an interconnection metal layer 6. The island-shaped structural layer 5 is covered by the interconnection metal layer 6 and connected to the interconnection metal layer 6. In an embodiment, the island-shaped electrode can be served as an anode electrode of the L-FER.

Due to the island-shaped electrode, the depletion region under the bias condition can be expanded to the region around the island-shaped electrode. Consequently, the electric field in the depletion region has more obvious depletion effect on the charge carriers. Furthermore, the leakage current of the L-FER is reduced, and the on-resistance of the L-FER in the on state is also reduced.

FIG. 1C is a schematic three-dimensional diagram of the group-III nitride lateral field effect rectifier (L-FER) according to the third embodiment of the present disclosure. In this embodiment, the group-III nitride L-FER includes a substrate 1, a buffer layer 2, a channel layer 3, a barrier layer 4, the island-shaped structural layer 5, the interconnection metal layer 6, an ohmic metal layer 91 of an anode electrode and a cathode electrode 92 from bottom to top.

For example, the substrate 1 is made of monocrystalline silicon, sapphire, gallium nitride, silicon carbide or diamond. In this embodiment, the substrate 1 is a silicon substrate.

The buffer layer 2 is made of GaN or AlGaN material, which contains C impurities. In addition, the thickness of the buffer layer 2 is usually ranged between 2 μm and 6 μm.

The channel layer 3 is made of GaN material. In addition, the thickness of the channel layer 3 is ranged between 200 nm and 500 nm.

The barrier layer 4 is made of AlGaN material. The thickness of the barrier layer 4 is ranged between 10 nm and 30 nm. In addition, the Al component incorporated in the barrier layer 4 is usually ranged between 10% and 30%.

A hole-shaped groove 41 is formed in the surface of the barrier layer 4. The depth of the hole-shaped groove 41 is ranged between 60 nm and 100 nm. In an embodiment, the hole-shaped groove 41 is formed after a portion of the barrier layer 4 and a portion of the channel layer 3 are etched.

The island-shaped structure layer 5 is made of a metallic material, a semiconductor material, or a combination thereof. For example, the metallic material is nickel, gold, palladium, platinum, titanium, titanium nitride, or a combination thereof. The semiconductor material is P-type GaN, P-type AlGaN, or a combination thereof. In addition, the thickness of the island-shaped structure layer is ranged between 80 nm and 120 nm.

The interconnection metal layer 6 is made of nickel, gold, palladium, platinum, titanium, titanium nitride, conductive glass, or a combination thereof.

The ohmic metal layer 91 in the anode electrode and the cathode electrode 92 are formed through a metal Ti/Al/Ni/Au depositing and annealing process.

In a fourth embodiment, a preparation method of the island-shaped electrode of the group-III nitride device is provided.

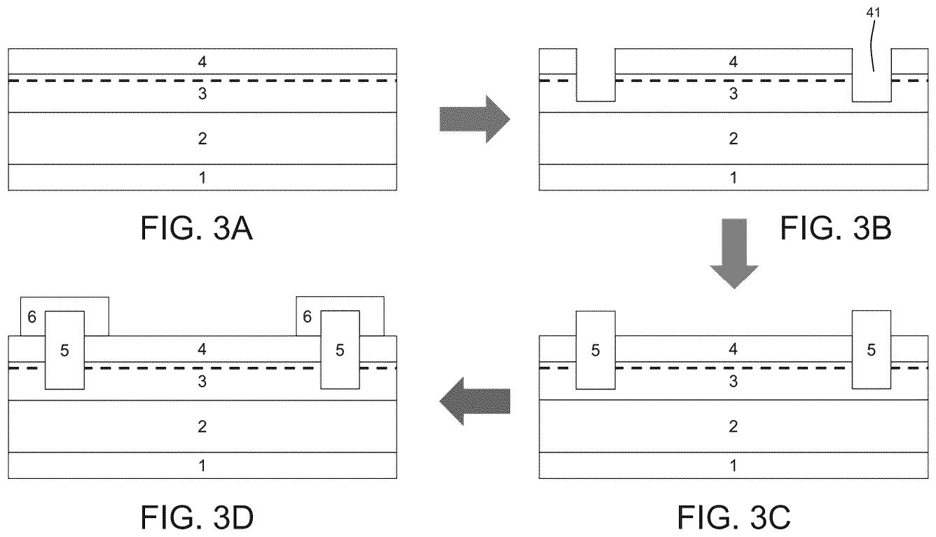

FIG. 3A is a schematic cross-sectional diagram illustrating the structure of the corresponding group-III nitride device in a step S1 of the preparation method. FIG. 3B is a schematic cross-sectional diagram illustrating the structure of the corresponding group-III nitride device in a step S2 of the preparation method. FIG. 3C is a schematic cross-sectional diagram illustrating the structure of the corresponding group-III nitride device in a step S3 of the preparation method. FIG. 3D is a schematic cross-sectional diagram illustrating the structure of the corresponding group-III nitride device in a step S4 of the preparation method. Hereinafter, the preparation method of the island-shaped electrode of the group-III nitride device is illustrated with reference to FIGS. 3A to 3D.

In the step S1, a heterojunction epitaxial wafer is provided. The heterojunction epitaxial wafer has a stack structure of a substrate 1, a buffer layer 2, a channel layer 3 and a barrier layer 4 from bottom to top.

In the step S2, a growth region of an island-shaped structure layer 5 (i.e., an island-shaped structure layer region) on the barrier layer 4 is defined, and an ion etching process is performed to remove a portion of the barrier layer 4 and a portion of the channel layer 3 corresponding to the island-shaped structure layer region. Consequently, a hole-shaped groove 41 is formed.

In the step S3, a metal layer is deposited in the hole-shaped groove 41. Consequently, the island-shaped structure layer 5 is formed.

In the step S4, a growth region of an interconnection metal layer 6 (i.e., an interconnection metal layer region) on the island-shaped structure layer 5 is defined, and the interconnection metal layer 6 is deposited on the interconnection metal layer region.

In the above steps, the island-shaped electrode fabrication technology and the device fabrication processes are integrated. For example, an inductively coupled plasma reactive ion etching technology is used to downwardly etch the heterojunction epitaxial wafer to form the hole-shaped groove 41. Furthermore, a self-alignment technology is adopted to deposit the island-shaped structure layer 5. After the deposition of the interconnection metal layer 6, the island-shaped electrode is formed.

Please refer to FIG. 3B. In the step S2, the region of the island-shaped structure layer 5 is defined on the barrier layer 4 through a photolithography etching process, and then the portion of the barrier layer 4 and the portion of the channel layer 3 corresponding to the region of the island-shaped structure layer 5 are removed through an inductively coupled plasma reactive ion etching process. Consequently, the hole-shaped groove 41 is formed. For example, the depth of the hole-shaped groove 41 is ranged between 60 nm and 100 nm.

Please refer to FIG. 3C. In the step S3, the island-shaped structure layer 5 is deposited in the hole-shaped groove 41. The island-shaped structure layer 5 is made of nickel, gold, palladium, platinum, titanium, titanium nitride, or a combination thereof. A good lateral Schottky contact between the island-shaped structure layer 5 and the heterojunction epitaxial wafer can be achieved within the hole-shaped groove 41.

Please refer to FIG. 3D. In the step S4, the growth region of the interconnection metal layer 6 on the island-shaped structure layer 5 is defined through a photolithography etching process, and then an interconnection metal is deposited. Consequently, the interconnection metal layer 6 is formed. The interconnection metal layer 6 is made of nickel, gold, palladium, platinum, titanium, titanium nitride, conductive glass, or a combination thereof.

In this embodiment, the metallic material is deposited on the island-shaped structure layer region and the interconnection metal layer region through an electron beam evaporation deposition process. In case that the metallic material has a higher melting point, the electron beam evaporation deposition process ensures faster and more uniform deposition of the metallic material on the desired areas.

In the inductively coupled plasma reactive ion etching process, an atmosphere containing boron trichloride and chlorine is ionized. Consequently, chlorine-based plasma is formed. The gas flow ratio of boron trichloride to chlorine is in a range between 1:1 and 5:1. In addition, the plasma power is controlled to be in a range between 10 W and 60 W.

Under the optimized plasma power, the etched groove morphology is improved without introducing excessive loss. Consequently, the island-shaped structure layer 5 deposited in the hole-shaped groove 41 and the heterojunction epitaxial wafer have the good lateral Schottky sidewall contact.

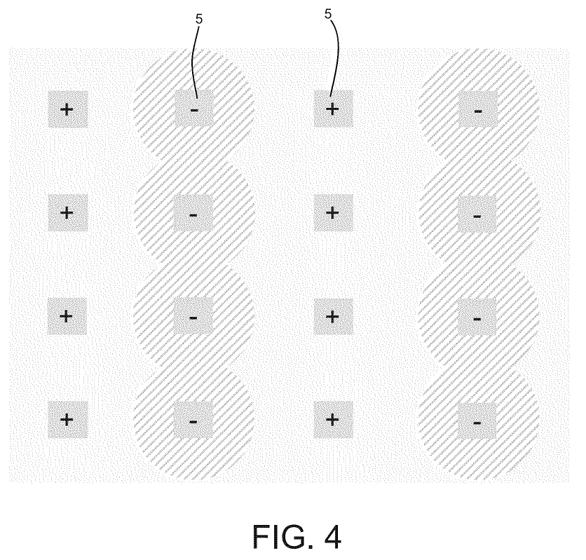

FIG. 4 is a schematic diagram illustrating a depletion method of the island-shaped electrode of the group-III nitride device shown in FIGS. 3A to 3D. After the hole-shaped groove 41 is etched in the channel layer 3/the barrier layer 4 and the island-shaped structure layer 5 and the interconnection metal layer 6 are deposited sequentially, the island-shaped electrode is formed. The depletion region under the bias condition can be expanded to the region around the island-shaped electrode. Consequently, the electric field in the depletion region has more obvious depletion effect on the charge carriers.

As mentioned above, the first embodiment provides a group-III nitride photodetector, the second embodiment provides a group-III nitride high electron mobility transistor (HEMT), and the third embodiment provides a group-III nitride lateral field effect rectifier (L-FER). The present disclosure also provides a preparation method for the island-shaped electrode of the group-III nitride device. The processes for forming the components other than the island-shaped electrode are similar to those of the conventional processes, and not redundantly described herein.

The above-described embodiments are only preferred embodiments of the present disclosure and are not intended to limit the disclosure in any form or substance. It should be noted that for those skilled in the art, various improvements and supplements can be made without departing from the illustration of the present disclosure. These improvements and supplements should also be regarded as within the scope of the present disclosure. Any slight changes, modifications, and variations made by those skilled in the art based on the technical disclosure above, without departing from the spirit and scope of the present disclosure, are equivalent embodiments of the present disclosure. Furthermore, any equivalent changes, modifications, and variations made to the above embodiments based on the essence of the present disclosure still fall within the scope of the technical solution of the present disclosure.

What is claimed is:

1. A group-III nitride device, comprising:
a heterojunction epitaxial wafer; and
at least one island-shaped electrode disposed on the heterojunction epitaxial wafer, wherein each of the at least one island-shaped electrode comprises an interconnection metal layer and at least one island-shaped structural layer, wherein the at least one island-shaped structural layer is covered by the interconnection metal layer and connected to the interconnection metal layer.

2. The group-III nitride device according to claim 1, wherein a depletion region of the at least one island-shaped electrode under a bias condition is expanded to a region around the at least one island-shaped electrode.

3. The group-III nitride device according to claim 1, wherein after the heterojunction epitaxial wafer is downwardly etched, at least one hole-shaped groove is formed, and each of the at least one island-shaped structural layer is formed in the corresponding hole-shaped groove.

4. The group-III nitride device according to claim 3, wherein a depth of the hole-shaped groove is ranged between 60 nm and 100 nm.

5. The group-III nitride device according to claim 3, wherein a thickness of the island-shaped structure layer is ranged between 80 nm and 120 nm, and the island-shaped structure layer and the heterojunction epitaxial wafer are contacted with each other in the hole-shaped groove.

6. The group-III nitride device according to claim 1, wherein the island-shaped structure layer is made of a metallic material, a semiconductor material, or a combination thereof.

7. The group-III nitride device according to claim 1, wherein the interconnection metal layer is made of nickel, gold, palladium, platinum, titanium, titanium nitride, conductive glass, or a combination thereof.

8. The group-III nitride device according to claim 1, wherein the group-III nitride device is a photodetector and the at least one island-shaped electrode is served as a positive electrode or a negative electrode of the photodetector.

9. The group-III nitride device according to claim 8, wherein the interconnection metal layer is a translucent interconnection metal layer.

10. The group-III nitride device according to claim 9, wherein a thickness of the translucent interconnection metal layer is ranged between 5 nm and 10 nm.

11. The group-III nitride device according to claim 1, wherein the group-III nitride device is a high electron mobility transistor and the at least one island-shaped electrode is served as a gate electrode of the high electron mobility transistor.

12. The group-III nitride device according to claim 1, wherein the group-III nitride device is a lateral field effect rectifier and the at least one island-shaped electrode is served as an anode electrode of the lateral field effect rectifier.

13. A preparation method of a group-III nitride device, the preparation method comprising steps of:
(S1) providing a heterojunction epitaxial wafer;
(S2) defining an island-shaped structure layer region on the heterojunction epitaxial wafer, and performing an etching process to form a hole-shaped groove in the heterojunction epitaxial wafer corresponding to the island-shaped structure layer region;
(S3) forming an island-shaped structure layer in the hole-shaped groove; and
(S4) defining an interconnection metal layer region and forming an interconnection metal layer on the interconnection metal layer region, wherein the island-shaped structural layer is covered by the interconnection metal layer and connected to the interconnection metal layer.

14. The preparation method according to claim 13, the island-shaped structural layer and the interconnection metal layer are collaboratively formed as at least one island-shaped electrode.

15. The preparation method according to claim 13, wherein in the step (S2), the etching process is an inductively coupled plasma reactive ion etching process.

16. The preparation method according to claim 15, wherein the heterojunction epitaxial wafer comprises a substrate, a buffer layer, a channel layer and a barrier layer from bottom to top, wherein in the step (S2), the hole-shaped groove is formed after a portion of the barrier layer and a portion of the channel layer corresponding to the island-shaped structure layer region are etched.

17. The preparation method according to claim 13, wherein in the step (S3), an electron beam evaporation deposition process is performed to deposit a material of the island-shaped structure layer in the hole-shaped groove, so that the island-shaped structure layer is formed.

18. The preparation method according to claim 13, wherein in the step (S4), an electron beam evaporation deposition process is performed to deposit a material of the interconnection metal layer on the interconnection metal layer region, so that the interconnection metal layer is formed.
